(19) United States
(12) Patent Application Publication
(10) Pub. No.: US 2012/0305054 A1
(43) Pub. Date: Dec. 6, 2012

(54) PHOTOELECTRIC CONVERSION MODULE

(76) Inventor: Hyun-Chul KIM, Yongin-si (KR)

(21) Appl. No.: 13/348,167

(22) Filed: Jan. 11, 2012

(30) Foreign Application Priority Data
May 31, 2011 (KR) 10-2011-0052397

(51) Int. Cl. H01L 31/048

(52) U.S. Cl. 136/251

(57) ABSTRACT

A photoelectric conversion module includes first and second substrates facing each other, sealing members, each of the plurality of sealing members defining a border at least partially enclosing one of a plurality of photoelectric cells, each of the sealing members being disposed between the first and second substrates, connection members formed between neighboring sealing members and for electrically connecting neighboring photoelectric cells to each other, and openings between the connection members and neighboring sealing members.

### BACKGROUND

1. Field

One or more embodiments relate to a photoelectric conversion module.

2. Description of the Related Art

Recently, research has been conducted on various photoelectric conversion devices for converting light energy into electric energy as an energy source for replacing fossil fuel, and solar batteries for obtaining energy from sunlight are attracting attention.

From among solar batteries having various operation principles, wafer-type silicon or crystalline solar batteries using p-n junctions of semiconductors are the most popular. However, these solar batteries require high manufacturing costs to form and require high purity semiconductor materials.

Unlike a silicon solar battery, a dye-sensitive solar battery mainly includes a photosensitive dye that receives light having a wavelength of visible light and generates excited electrons, a semiconductor material that receives the excited electrons, and an electrolyte that reacts with electrons returning from an external circuit. The dye-sensitive solar battery has much higher efficiency of photoelectric conversion than general solar batteries and thus is regarded as a next-generation solar battery.

### SUMMARY

According to one or more embodiments, a photoelectric conversion module may include first and second substrates facing each other; a plurality of sealing members, each of the plurality of sealing members defining a border at least partially enclosing one of a plurality of photoelectric cells, each of the sealing members being disposed between the first and second substrates, connection members between neighboring sealing members for electrically connecting neighboring photoelectric cells to each other, and openings between the connection members and neighboring sealing members.

The photoelectric conversion module may further include blocking members, separate from one another, between the first and second substrates along edges of the first and second substrates.

The blocking members may include first blocking members aligned with the openings.

A width of the first blocking members may be greater than a width of the connection members.

Each sealing member may define a generally rectangular structure including a pair of parallel, opposing long sides and a pair of parallel, opposing short sides extending between and connecting the pair of long sides, the blocking members including second blocking members, the second blocking members being outside of the generally rectangular structure.

The second blocking members may be aligned with the opposing short sides of the sealing members.

The blocking members may include first blocking members and second blocking members, the first blocking members including a surface facing the openings and the connection members, each sealing member may define a generally rectangular structure, the second blocking members may be formed outside of the border defined by the sealing members, the first blocking members may be aligned in a first row, the second blocking members may be aligned in a second row, the second row being spaced from the first row and the first blocking member and the second blocking members being staggered with respect to one another.

Each of the sealing members may individually surround each of the plurality of photoelectric cells, and the connection members may be disposed between neighboring sealing members.

Each of the sealing members may include a spacer formed on one of the first and second substrates and a curable resin surrounding at least a portion of the spacer.

The spacer may protrude from the second substrate toward the first substrate, and the curable resin may couple a protruding portion of the spacer to the first substrate to provide an air-tight seal.

Each of the connection members may include first and second conductive bumps respectively formed on the first and second substrates; and an elastic conductor for elastically connecting the first and second conductive bumps.

According to one or more embodiments, a photoelectric conversion module may include first and second substrates facing each other; sealing members between the first and second substrates, the sealing members defining a plurality of photoelectric cells, connection members between neighboring sealing members for electrically connecting neighboring photoelectric cells to each other, and openings between the connection members and neighboring sealing members.

The openings may be at front and back sides of the connection members.

The openings may surround the connection members.

The photoelectric conversion module may further include first blocking members disposed between the first and second substrates, the first blocking members include a surface facing the connection members.

A width of the first blocking members may be greater than a width of the connection members.

The sealing members may define a generally rectangular structure between the first and second substrates, the generally rectangular structure including a pair of parallel, opposing long sides, and a pair of parallel, opposing short sides extending between and connecting the parallel, opposing long sides.

The photoelectric conversion module may further include second blocking members, the second blocking members being disposed between the first and second substrates along the short sides of the sealing members.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a plan view of a photoelectric conversion module according to an embodiment;

FIG. 2 illustrates an exploded perspective view of the photoelectric conversion module illustrated in FIG. 1;

FIG. 3 illustrates a diagram showing gas discharge paths of the photoelectric conversion module illustrated in FIG. 1;

FIG. 4 illustrates a plan view of a conventional photoelectric conversion module shown for comparison with embodiments;

FIG. 5 illustrates a magnified view of a portion V in FIG. 4;

FIG. 6 illustrates a cross-sectional view cut along a line VI-VI′ in FIG. 1; and

FIG. 7 illustrates a vertical cross-sectional view of a photoelectric conversion module according to other embodiments.

### DETAILED DESCRIPTION

Korean Patent Application No. 10-2011-0052397, filed on May 31, 2011, in the Korean Intellectual Property Office, and entitled: “Photoelectric Conversion Module,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

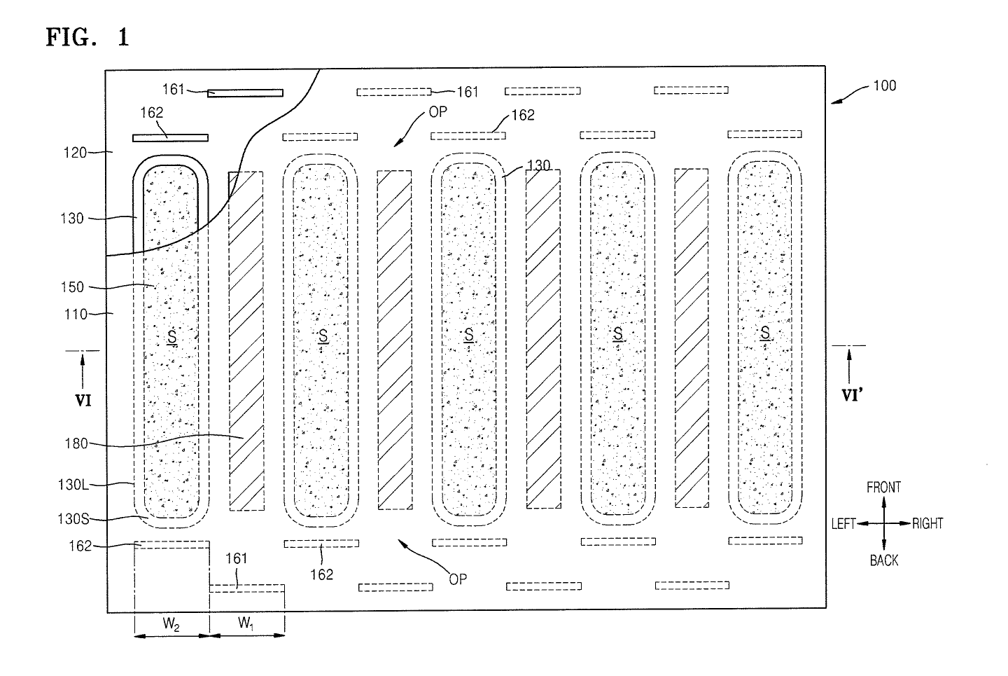

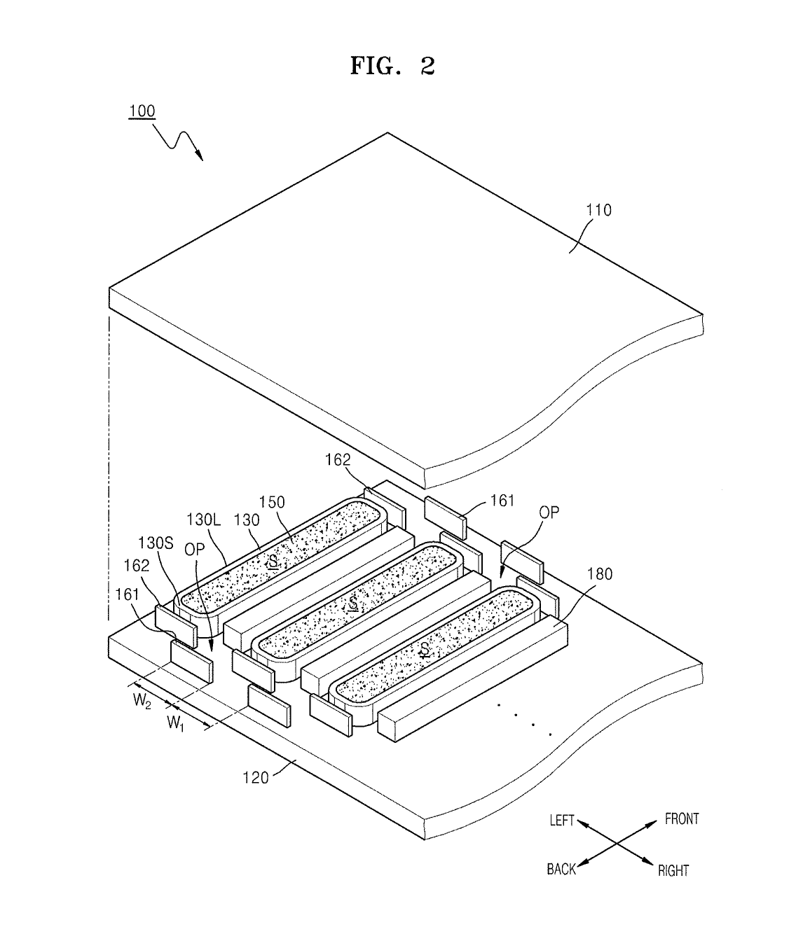

FIG. 1 illustrates a plan view of a photoelectric conversion module 100 according to an embodiment. FIG. 2 illustrates an exploded perspective view of the photoelectric conversion module 100 illustrated in FIG. 1.

Referring to FIGS. 1 and 2, the photoelectric conversion module 100 may include a plurality of photoelectric cells S. The photoelectric cells S may at least be partially surrounded by sealing members 130. According to an embodiment, each of the sealing members 130 may form a generally rectangular structure that separately surrounds each of the photoelectric cells S. The sealing members 130 may be independently formed to individually surround the photoelectric cells S. According to an embodiment, each of the photoelectric cells S may be disposed within a rectangular structure formed by the sealing members 130.

Connection members 180 may be disposed between neighboring sealing members 130. The connection members 180 may electrically modularize the photoelectric cells S by electrically connecting neighboring photoelectric cells S. The photoelectric cells S may be modularized, for example, by being separately connected via the connection members 180 to neighboring photoelectric cells S in series or in parallel and by being physically supported between first and second substrates 110 and 120.

An electrolyte 150 may be filled into the photoelectric cells S, and may be sealed by the sealing members 130 disposed along edges of the photoelectric cells S. The sealing members 130 may be formed around the electrolyte 150 to surround the electrolyte 150, and seal the electrolyte 150 to prevent leakage of the electrolyte 150.

The connection members 180 may connect neighboring photoelectric cells S, and openings OP may be formed at front and back sides of the connection members 180 along a lengthwise direction of the connection members 180. In other words, the openings OP may be provided between each of the connection members 180 and a neighboring sealing member 130, and along opposing (front and back) ends of the connection members 180. According to an embodiment, each of the connection members 180 is surrounded by a different one of the openings OP.

The connection members 180 may not be accommodated in a sealed space and may be exposed through the openings OP. For example, since the connection members 180 may be exposed through the openings OP, the connection members 180 may not be blocked by the sealing members 130, which surround the photoelectric cells S, or by any other members structurally connected to the sealing members 130. According to some embodiments, the connection members 180 may be surrounded by an external packing (not shown) of the photoelectric conversion module 100. Thus, the connection members 180 may not be actually exposed to the outside of the photoelectric conversion module 100.

The openings OP may provide gas discharge paths for discharging a residual gas. For example, the openings OP may provide gas discharge paths for discharging a residual gas generated when the first and second substrates 110 and 120, between which the sealing members 130 are disposed, are pressed and bonded to each other.

According to an embodiment, during a bonding process of the first and second substrates 110 and 120, the first and second substrates 110 and 120 may be fixed by a clamp, and heated and pressed by an external heat source, e.g., a laser, and a presser. The first and second substrates 110 and 120 may, thereby, be combined with each other. A residual gas may be generated if air between the first and second substrates 110 and 120, or a gas generated when the sealing members 130 are heated, is not completely discharged and remains. The residual gas may generate internal gas pressure. Thus, the residual gas may generate bubbles in the sealing members 130 when the sealing members 130 have not yet been cured. The generated bubbles may cause a fatal problem, e.g., penetration of the electrolyte 150 into or through the sealing members 130, and may, thereby, reduce the reliability of the photoelectric conversion module 100.

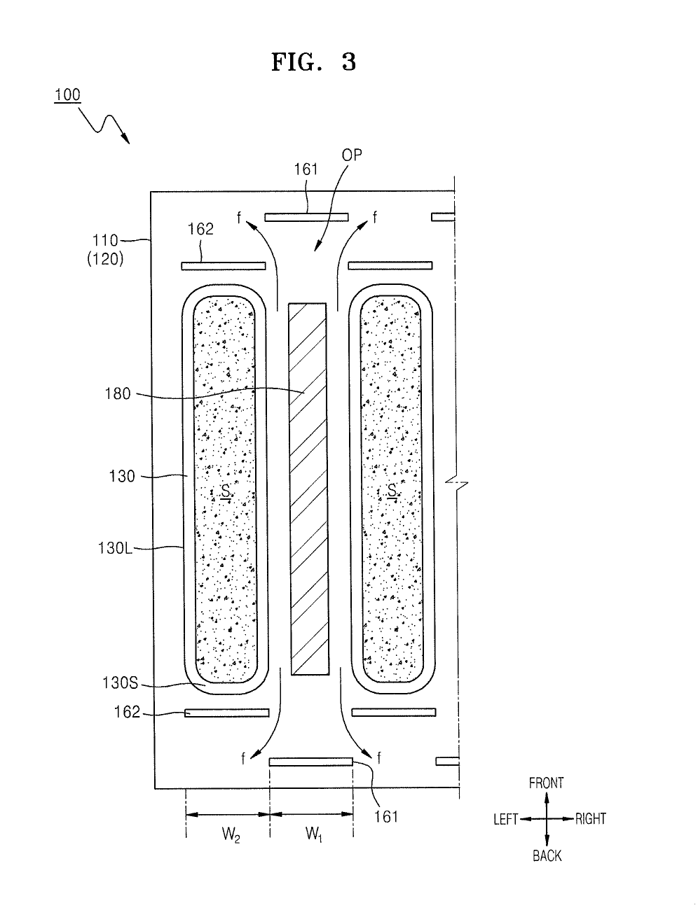

FIG. 3 illustrates a diagram showing gas discharge paths of the photoelectric conversion module 100 illustrated in FIG. 1. Referring to FIG. 3, as described above, the openings OP may provide gas discharge paths f for discharging a residual gas. Since the residual gas may be discharged through the openings OP, internal pressure due to the residual gas may not be accumulated. As such, bubbles may not be generated in the sealing members 130 when the sealing members 130 have not yet been cured.

Referring to FIG. 1, first and second blocking members 161 and 162 may be formed in discontinuous patterns along edges of the first and second substrates 110 and 120. The first and second blocking members 161 and 162 may support and ensure a certain distance between the first and second substrates 110 and 120. Also, the first and second blocking members 161 and 162 may prevent oxidation of the connection members 180, and may prevent penetration of impurities.

For example, in order to prevent penetration of impurities and to increase the convenience of management in a manufacturing process of the photoelectric conversion module 100, the first and second blocking members 161 and 162 may be formed in discontinuous patterns along the edges of the first and second substrates 110 and 120. In more detail, the first blocking members 161 may be along outer edges of the first and second substrates 110 and 120, generally in alignment with opposing ends of the connection members 180. In other words, the first and second blocking members 161 and 162 may be alternately disposed. The second blocking members 162 may be generally aligned with opposing ends of the sealing members 130. The first and second blocking members 161 and 162 may be spaced apart from each other in discontinuous patterns. For example, the first blocking members 161 may be horizontally aligned in a first row, and the second blocking members 162 may be horizontally aligned in a second row. The first row may be spaced from the second row. The gas discharge paths f (see FIG. 3) for discharging a residual gas may be ensured through the space between the first and second blocking members 161 and 162.

The first blocking members 161 may be disposed at outer sides of the connection members 180, and may include at least one surface that faces the openings OP formed at the front and back sides of the connection members 180, along the direction in which the connection members 180 extend. For example, the openings OP may extend along opposing sides of the connection members 180. The first blocking members 161 may be disposed a relatively large distance away from the connection members 180, and the openings OP may be formed between the connection members 180 and the first blocking members 161. The first blocking members 161 may be formed to have a first width W1 that is greater than that of the connection members 180.

Each of the sealing members may define a border at least partially enclosing the photoelectric cells S. According to an embodiment, each of the sealing members 130 surrounding the generally rectangular photoelectric cells S may include a pair of long sides 130L and a pair of short sides 130S, extending between the pair of long sides 130L. The second blocking members 162 may be parallel to the short sides 130S of the sealing members. The second blocking members 162 may extend along short sides 130S of the sealing members 130. The second blocking members 162 may have a second width W2.

The first and second blocking members 161 and 162 may be at different locations in a front-back direction. For example, the first blocking members 161 may be disposed at a relatively large distance from the connection members 180, and the second blocking members 162 may be disposed at a relatively small distance from the sealing members 130. In other words, the distance between the first blocking members 161 and the connection members 180 may be greater than the distance between the second blocking members 162 and the sealing members 130.

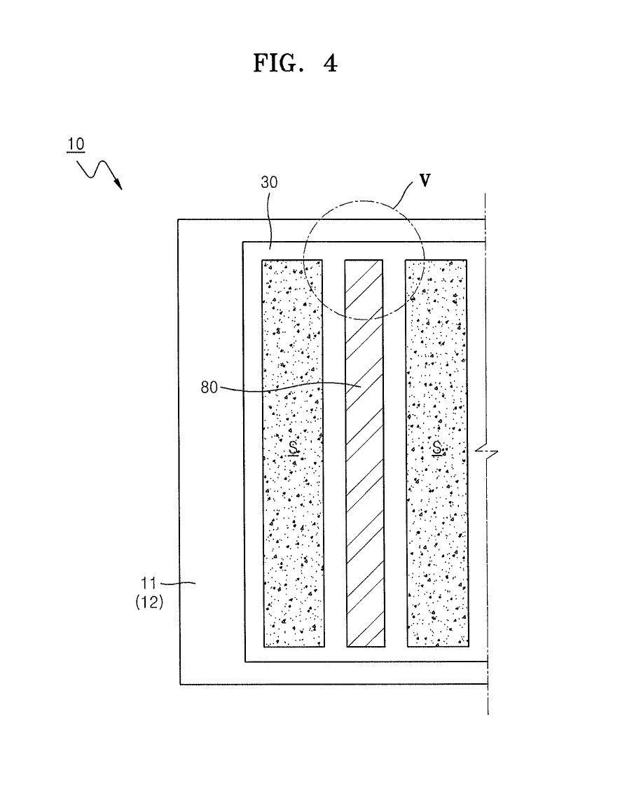

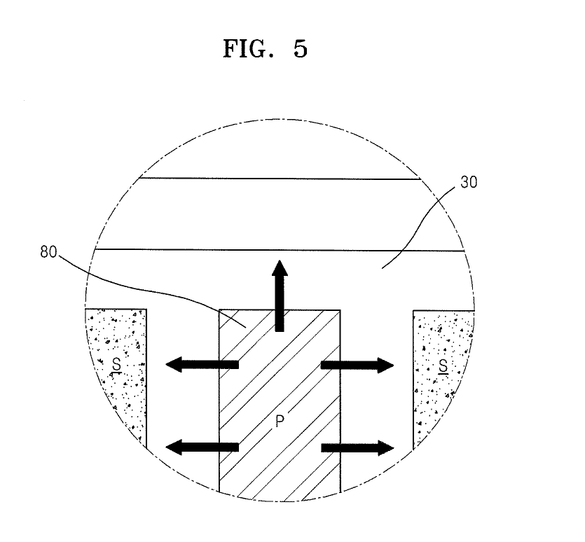

FIG. 4 illustrates a plan view of a conventional photoelectric conversion module 10 shown for comparison with embodiments. FIG. 5 illustrates a magnified view of a portion V illustrated in FIG. 4. Referring to FIG. 4, each of a plurality of photoelectric cells S and a sealing member 30 surrounding each of the photoelectric cells S are disposed between first and second substrates 11 and 12. The sealing member 30 is disposed along edge regions of the first and second substrates 11 and 12, extends between neighboring photoelectric cells S, and surrounds each of the photoelectric cells S. Neighboring photoelectric cells S may be electrically connected to each other via connection members 80 disposed in spaces surrounded by the sealing member 30.

Referring to FIG. 5, each of the connection members 80 is surrounded by the sealing member 30. A residual gas that is not completely discharged in a bonding process of the first and second substrates 11 and 12, or is generated in a curing process of the sealing member 30 accumulates, thereby, generating internal pressure P in a sealed space. The internal pressure P causes defects, such as air holes, in the sealing member 30 when the sealing member 30 has not yet been cured. As such, the durability of the sealing member 30 may be reduced and an electrolyte sealed by the sealing member 30 may leak.

In contrast, as illustrated in FIG. 3, according to embodiments, the openings OP between neighboring sealing members 130, and more particularly, the openings OP between neighboring sealing members 130 and at the front and back sides of the connection members 180 along the direction in which the connection members 180 extend, may provide gas discharge paths f for discharging a residual gas and may resolve many problems associated with an accumulation of internal pressure.

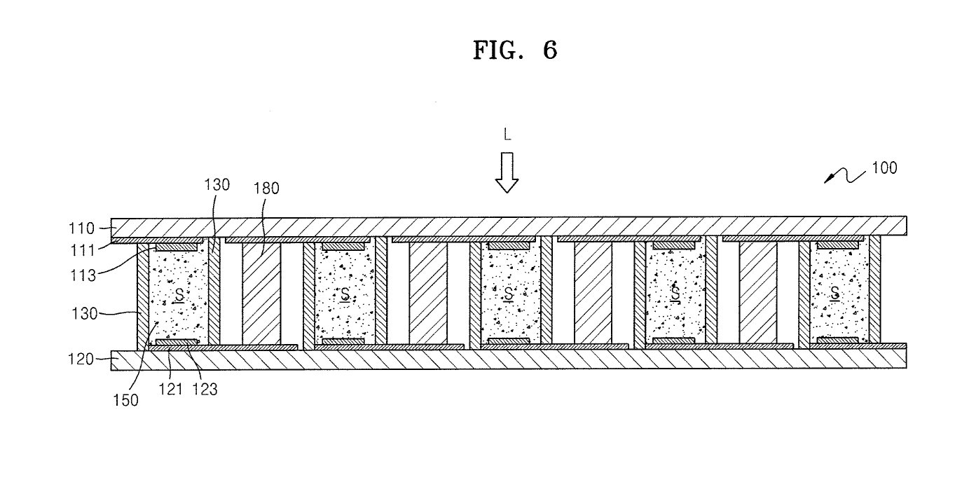

FIG. 6 illustrates a cross-sectional view cut along a line VI-VI′ illustrated in FIG. 1. Referring to FIG. 6, the photoelectric conversion module 100 may include the first and second substrates 110 and 120 facing each other, and the photoelectric cells S (surrounded by the sealing members 130) between the first and second substrates 110 and 120. The connection members 180 may be formed between neighboring photoelectric cells S, and may connect the neighboring photoelectric cells S to each other. The connection members 180 may be disposed parallel to neighboring photoelectric cells S.

Photoelectrodes 111 and counter electrodes 121 may be formed on the first and second substrates 110 and 120, respectively. The first and second substrates 110 and 120 may be bonded to each other with a predetermined gap, via the sealing members 130. Semiconductor layers 113, in which a photosensitive dye to be excited by light L is absorbed, are formed on the photoelectrodes 111. The electrolyte 150 may be provided between the semiconductor layers 113 and the counter electrodes 121.

The first substrate 110 may be formed of a transparent material, i.e., a material having a high light transmittance. For example, the first substrate 110 may be a glass substrate or a resin film. A resin film generally has flexibility and thus is appropriate for when nonrigidity is required.

The photoelectrodes 111 may function as negative electrodes of the photoelectric conversion module 100. In more detail, the photoelectrodes 111 may provide current paths by receiving electrons generated due to photoelectric conversion. The light L incident through the photoelectrodes 111 may function as a source for exciting the photosensitive dye absorbed into the semiconductor layers 113. The photoelectrodes 111 may include a transparent conducting oxide (TCO) having electrical conductivity and transparency, e.g., indium tin oxide (ITO), fluorine tin oxide (FTO), or antimony tin oxide (ATO). The photoelectrodes 111 may further include metal electrodes having excellent electrical conductivity, e.g., gold (Ag), silver (Au), or aluminum (Al) electrodes. The metal electrodes may be used to reduce the electrical resistance of the photoelectrodes 111 and may be formed in a stripe pattern or a mesh pattern.

The semiconductor layers 113 themselves may be formed of a semiconductor material, e.g., a metal oxide such as cadmium (Cd), zinc (Zn), indium (In), lead (Pb), molybdenum (Mo), tungsten (W), antimony (Sb), titanium (Ti), silver (Ag), manganese (Mn), tin (Sn), zirconium (Zr), strontium (Sr), gallium (Ga), silicon (Si), or chromium (Cr) oxide. The semiconductor layers 113 may absorb the photosensitive dye to increase the efficiency of photoelectric conversion. For example, the semiconductor layers 113 may be formed by coating a paste, in which semiconductor particles having diameters of about 5 nm to about 1000 nm are dispersed, on the photoelectrodes 111 formed on the first substrate 110, and heating or pressing the paste by applying a certain degree of heat or pressure.

The photosensitive dye absorbed into the semiconductor layers 113 may absorb the light L incident through the first substrate 110, and electrons of the photosensitive dye may be excited from a base state to an excitation state. The excited electrons may be transited to a conduction band of the semiconductor layers 113 by using electrical coupling between the photosensitive dye and the semiconductor layers 113. The excited electrons may reach the photoelectrodes 111 through the semiconductor layers 113, and exit through the photoelectrodes 111, thereby forming a driving current for driving an external circuit.

For example, the photosensitive dye absorbed into the semiconductor layers 113 may be formed of molecules for absorbing visible light and rapidly moving electrons to the semiconductor layers 113 in a light excitation state. The photosensitive dye may be in the form of a liquid, a gel that is a half-solid, or a solid. For example, the photosensitive dye absorbed into the semiconductor layers 113 may be a ruthenium (Ru)-based photosensitive dye. A predetermined photosensitive dye may be absorbed into the semiconductor layers 113 by dipping the first substrate 110 on which the semiconductor layers 113 are formed into a solution including the photosensitive dye.

The electrolyte 150 may be a redox electrolyte including an oxidant and reductant pair, and may be in the form of a solid, a gel, or a liquid.

The second substrate 120 facing the first substrate 110 may not require transparency. However, in order to increase the efficiency of photoelectric conversion, the second substrate 120 may be formed of a transparent material so that the light L is received into the photoelectric conversion module 100 from two sides. The second substrate may be formed of the same material as the first substrate 110. In particular, if the photoelectric conversion module 100 is used in a building integrated photovoltaic (BIPV) system to be mounted on a structure, such as a window frame, two sides of the photoelectric conversion module 100 may have transparency so as not to block the light L from entering from the outside.

The counter electrodes 121 may function as positive electrodes of the photoelectric conversion module 100. The photosensitive dye absorbed into the semiconductor layers 113 may absorb the light L, which excites electrons of the photosensitive dye. The excited electrons may exit through the photoelectrodes 111. Meanwhile, the photosensitive dye, having lost electrons, may be reduced by receiving electrons when the electrolyte 150 is oxidized. The electrolyte 150 may be reduced by electrons reaching the counter electrodes 121, via the external circuit, thereby completing a photoelectric conversion operation.

For example, the counter electrodes 121 may be formed of a TCO having electrical conductivity and transparency, e.g., ITO, FTO, or ATO. The counter electrodes 121 may further include metal electrodes having excellent electrical conductivity, e.g., Au, Ag, or Al electrodes. The metal electrodes may be used to reduce the electrical resistance of the counter electrodes 121 and may be formed in a stripe pattern or a mesh pattern.

Catalyst layers 123 may be formed on the counter electrodes 121. The catalyst layers 123 may be formed of a material functioning as a reduction catalyst for providing electrons, e.g., a metal such as platinum (Pt), gold (Au), silver (Ag), copper (Cu), or aluminum (Al), a metal oxide such as tin oxide (SnO), or a carbon (C)-based material such as graphite.

According to an embodiment, the sealing members 130, formed between the first and second substrates 110 and 120, may maintain a certain distance between the first and second substrates 110 and 120, while enclosing the photoelectric cells S. Also, the sealing members 130 may surround and seal the electrolyte 150 injected into the photoelectric conversion module 100. The sealing members 130 may be formed of, for example, a thermosetting resin, such as an epoxy, a thermoplastic resin, such as an ionomer, or a photocurable resin such as a UV curable epoxy.

The connection members 180 may be disposed adjacent to the sealing members 130 so as to electrically connect the photoelectric cells S. For example, the connection members 180 may be formed between neighboring sealing members 130.

The connection members 180 may extend vertically between the first and second substrates, so as to contact the photoelectrodes 111 and the counter electrodes 121, which may be formed on and under the connection members 180, respectively. For example the photoelectrodes 111 and the counter electrodes 121 may contact opposing ends of the connection members 180. The connection members 180 may connect the photoelectrodes 111 and the counter electrodes 121 with neighboring photoelectric cells S in series. The connection members 180 may include a metallic material having excellent conductivity, e.g., silver (Ag).

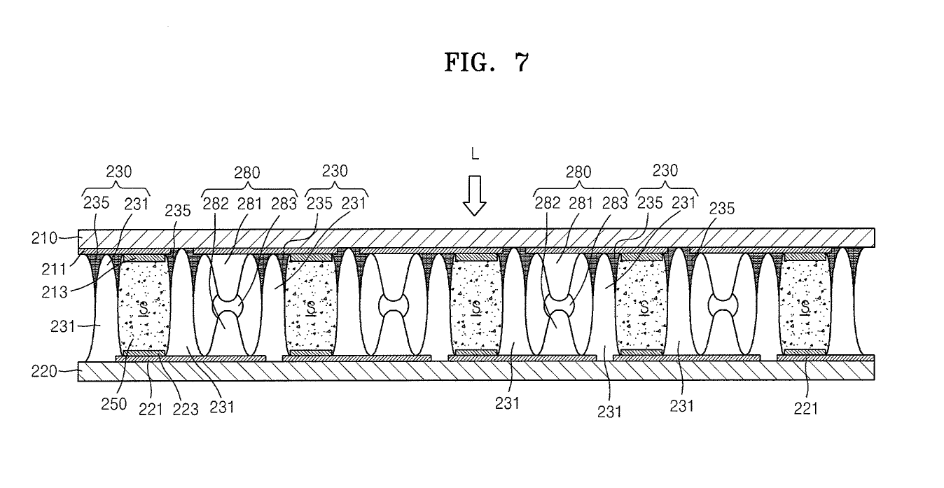

FIG. 7 illustrates a vertical cross-sectional view of a photoelectric conversion module according to another embodiment. Referring to FIG. 7, a first substrate 210 on which semiconductor layers 213 and photoelectrodes 211 are formed may be bonded to a second substrate 220 on which catalyst layers 223 and counter electrodes 221 are formed. According to an embodiment, sealing members 230 may be disposed between the first and second substrates 210 and 220. The sealing members 230 may enclose the photoelectric cells S and seal an electrolyte 250 in the photoelectric cells S.

Connection members 280 may be disposed between the sealing members 230, which electrically connect neighboring photoelectric cells S to each other. In more detail, each of the connection members 280 may extend vertically between the first substrate 210 and the second substrate 220. Each of the connection members 280 may contact the photoelectrode 211 of one photoelectric cell S and the counter electrode 221 of an adjacent photoelectric cell S, thereby, electrically connecting the photoelectrode 211 and the counter electrode 221 of neighboring photoelectric cells S in series.

Each of the connection members 280 may include conductive bumps 281 and 282 formed on the first and second substrates 210 and 220, respectively, and an elastic conductor 283 for elastically connecting the conductive bumps 281 and 282. The conductive bumps 281 and 282 may be formed on the first and second substrates 210 and 220, respectively, and may be rigid. The elastic conductor 283 for connecting the conductive bumps 281 and 282 to each other may be formed of a curable conductive metal, and may be solidified by performing an appropriate curing process. For example, the conductive bumps 281 and 282 may be formed of an Ag conductor, and the elastic conductor 283 may be formed of a curable Ag conductor.

Each of the sealing members 230 may include a spacer 231 and a curable resin 235 formed to surround an upper portion of the spacer 231. In more detail, the spacer 231 may maintain a certain distance between the first and second substrates 210 and 220. For example, as illustrated in FIG. 7, the spacer 231 may be formed on the second substrate 220, and may protrude from the second substrate 220 toward the first substrate 210. According to an embodiment, the spacer 231 may protrude from the second substrate 220 toward the first substrate 210, and the upper portion of the spacer 231 may contact the first substrate 210. In order to seal the electrolyte 250, airtight coupling may be required between the upper portion of the spacer 231 and the first substrate 210, and the curable resin 235 may be coated on the upper portion of the spacer 231.

For example, the curable resin 235 may be coated on the first substrate 210 corresponding to the spacer 231, and may cover and surround the upper portion of the spacer 231 in a bonding process of the first and second substrates 210 and 220. When the first and second substrates 210 and 220 are bonded, the curable resin 235 may be cured by performing an appropriate curing process such as a heat curing process or a light curing process, and the first substrate 210 may be air-tightly coupled to the upper portion of the spacer 231.

When the first and second substrates 210 and 220 are bonded, the conductive bump 281 on the first substrate 210 and the conductive bump 282 on the second substrate 220 may contact each other via the elastic conductor 283. By curing the elastic conductor 283, the conductive bumps 281 and 282 on the first and second substrates 210 and 220 may be electrically connected, and the connection members 280 may thereby be formed. In this case, the elastic conductor 283 may be elastically deformed between the conductive bumps 281 and 282 on the first and second substrates 210 and 220 so as to firmly connect the conductive bumps 281 and 282.

As shown, in FIG. 7, the spacers 231 of the sealing members 230 may be formed on the second substrate 220, or a counter substrate, and the curable resin 235 for sealing the upper portions of the spacers 231 may be formed on the first substrate 210, that is, a light-receiving substrate. However, the location of the spacers 231 and the curable resin 235 are not limited thereto. For example, the spacers 231 of the sealing members 230 may be formed on the first substrate 210 or a light-receiving substrate, and the curable resin 235 for sealing lower portions of the spacers 231 may be formed on the second substrate 220 or a counter substrate.

As described above, according to one or more of the above embodiments, a defect of the sealing members due to accumulation of a residual gas and an increase in internal pressure, may be prevented. The residual gas may accumulate during a bonding process of first and second substrates or a curing process of sealing members disposed between the first and second substrates. Also, a reduction in sealability of an electrolyte due to the defect of the sealing members may be prevented.

One or more embodiments may include a photoelectric conversion module capable of preventing damage of a sealing structure of an electrolyte due to accumulation of internal pressure or retention of an impure gas in a manufacturing process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoelectric conversion module, comprising:
first and second substrates facing each other;
a plurality of sealing members, each of the plurality of sealing members defining a border at least partially enclosing one of a plurality of photoelectric cells, each of the sealing members being disposed between the first and second substrates;
connection members between neighboring sealing members for electrically connecting neighboring photoelectric cells to each other; and
openings between the connection members and neighboring sealing members.

2. The photoelectric conversion module as claimed in claim 1, further comprising blocking members, separate from one another, between the first and second substrates along edges of the first and second substrates.

3. The photoelectric conversion module as claimed in claim 2, wherein the blocking members include first blocking members, the first blocking members being aligned with the openings.

4. The photoelectric conversion module as claimed in claim 3, wherein a width of the first blocking members is greater than a width of the connection members.

5. The photoelectric conversion module as claimed in claim 2, wherein each sealing member defines a generally rectangular structure including a pair of parallel, opposing long sides and a pair of parallel, opposing short sides extending between and connecting the pair of long sides, the blocking members including second blocking members, the second blocking members being outside of the generally rectangular structure.

6. The photoelectric conversion module as claimed in claim 5, wherein the second blocking members are aligned with the opposing short sides of the sealing members.

7. The photoelectric conversion module as claimed in claim 2, wherein first blocking members of the blocking members are formed to face the openings along the direction in which the connection members extend,
wherein the second blocking members of the blocking members are formed at outer sides of the sealing members, and
wherein the first and second blocking members are formed in discontinuous patterns.

8. The photoelectric conversion module as claimed in claim 2, wherein:
the blocking members include first blocking members and second blocking members, the first blocking members including a surface facing the openings and the connection members,
each sealing member defines a generally rectangular structure,
the second blocking members are formed outside of the border defined by the sealing members,
the first blocking members are aligned in a first row,
the second blocking members are aligned in a second row, the second row being spaced from the first row, and
the first blocking members and the second blocking members are staggered with respect to one another.

9. The photoelectric conversion module as claimed in claim 1, wherein each of the sealing members individually surround each of the plurality of photoelectric cells, and the connection members are disposed between neighboring sealing members.

10. The photoelectric conversion module as claimed in claim 1, wherein each of the sealing members includes:
a spacer on one of the first and second substrates; and
a curable resin surrounding at least a portion of the spacer.

11. The photoelectric conversion module as claimed in claim 10, wherein the spacer protrudes from the second substrate toward the first substrate, and the curable resin couples a protruding portion of the spacer to the first substrate to provide an air-tight seal.

12. The photoelectric conversion module as claimed in claim 1, wherein each of the connection members includes:
first and second conductive bumps respectively formed on the first and second substrates; and
an elastic conductor for elastically connecting the first and second conductive bumps.

13. A photoelectric conversion module, comprising:
first and second substrates facing each other;
sealing members between the first and second substrates, the sealing members defining a plurality of photoelectric cells,
connection members between neighboring sealing members for electrically connecting neighboring photoelectric cells to each other; and
openings between the connection members and neighboring sealing members.

14. The photoelectric conversion module as claimed in claim 13, wherein the openings are at front and back sides of the connection members.

15. The photoelectric conversion module as claimed in claim 13, wherein the openings surround the connection members.

16. The photoelectric conversion module as claimed in claim 13, further comprising first blocking members disposed between the first and second substrates, the first blocking members including a surface facing the connection members.

17. The photoelectric conversion module as claimed in claim 16, wherein a width of the first blocking members is greater than a width of the connection members.

18. The photoelectric conversion module as claimed in claim 13, wherein the sealing members define a generally rectangular structure between the first and second substrates, the generally rectangular structure including a pair of parallel, opposing long sides, and a pair of parallel, opposing short short sides extending between and connecting the parallel, opposing long sides.

19. The photoelectric conversion module as claimed in claim 18, further including second blocking members disposed between the first and second substrates along the short sides of the sealing members.

20. The photoelectric conversion module as claimed in claim 13, wherein the sealing members are independently formed to individually surround each of the plurality of photoelectric cells.
